(19) United States
(12) Patent Application Publication
(10) Pub. No.: US 2014/0240050 A1
(43) Pub. Date: Aug. 28, 2014

(54) POWER CIRCUIT

(71) Applicant: KABUSHIKI KAISHA TOSHIBA, Tokyo (JP)

(72) Inventor: Kan SHIMIZU, Saitama (JP)

(73) Assignee: KABUSHIKI KAISHA TOSHIBA, Tokyo (JP)

(21) Appl. No.: 14/173,207

(22) Filed: Feb. 5, 2014

(30) Foreign Application Priority Data
Feb. 28, 2013 (JP) 2013-039483

(51) Int. Cl. H03F 1/02

(52) U.S. Cl. CPC H03F 1/0211
USPC 330/297

(57) ABSTRACT

A power circuit includes a bridge circuit connected to a first node by which an output voltage is supplied to a load circuit including an amplifier containing a CMOS inverter, and configured to generate a current flowing in a first current channel and a current flowing in a second current channel in accordance with a voltage difference between the output voltage and a predetermined set voltage to be supplied to the load circuit, and a current amplifier configured to generate a current flowing in a third current channel to the load circuit in accordance with an input source voltage and a difference between the current flowing in the first current channel and the current flowing in the second current channel. The predetermined set voltage that is supplied to the load circuit achieves the smallest transconductance during normal operation of the amplifier.

### CROSS-REFERENCE TO RELATED APPLICATION

This application is based upon and claims the benefit of priority from Japanese Patent Application No. 2013-039483, filed Feb. 28, 2013, the entire contents of which are incorporated herein by reference.

### FIELD

Embodiments described herein relate generally to a power circuit for driving a load circuit.

### BACKGROUND

A clock circuit containing a crystal oscillator circuit is driven by an AC power source in the normal condition, and driven by charges accumulated in a charged capacitor in the sleep condition.

According to this type of clock circuit, the crystal oscillator circuit consumes a large amount of current, and therefore reduction of the current consumption is needed as much as possible. A constant-current control circuit which limits the current consumption of the crystal oscillator circuit may be available as a method to achieve this reduction.

### DESCRIPTION OF THE DRAWINGS

FIG. 1 is a circuit diagram of a power circuit according to a first embodiment.

FIG. 2 is a graph showing changes in currents in relation to a gate voltage of a transistor.

FIG. 3 is a circuit diagram of a power circuit according to a second embodiment.

FIG. 4 is a circuit diagram of a power circuit according to a third embodiment.

FIG. 5 is a circuit diagram of a power circuit according to a fourth embodiment.

FIG. 6 is a circuit diagram of a power circuit according to a fifth embodiment.

### DETAILED DESCRIPTION

Embodiments provide a power circuit that is configured to be hardly affected by variations of elements during manufacture, and capable of reducing current consumption without increasing circuit area.

According to an embodiment, a power circuit includes a bridge circuit connected to a first node or output node, and configured to generate a differential current of a first current flowing in a first current channel and a second current flowing in a second current channel in accordance with a voltage difference between an output voltage and a predetermined set voltage to be supplied to the load circuit, and a current amplifier configured to generate a third current flowing in a third current channel to the load circuit in accordance with a difference between the first current and the second current. The predetermined set voltage that is supplied to the load circuit achieves the smallest transconductance for a normal operation of the amplifier.

Embodiments are hereinafter described with reference to the drawings.

### First Embodiment

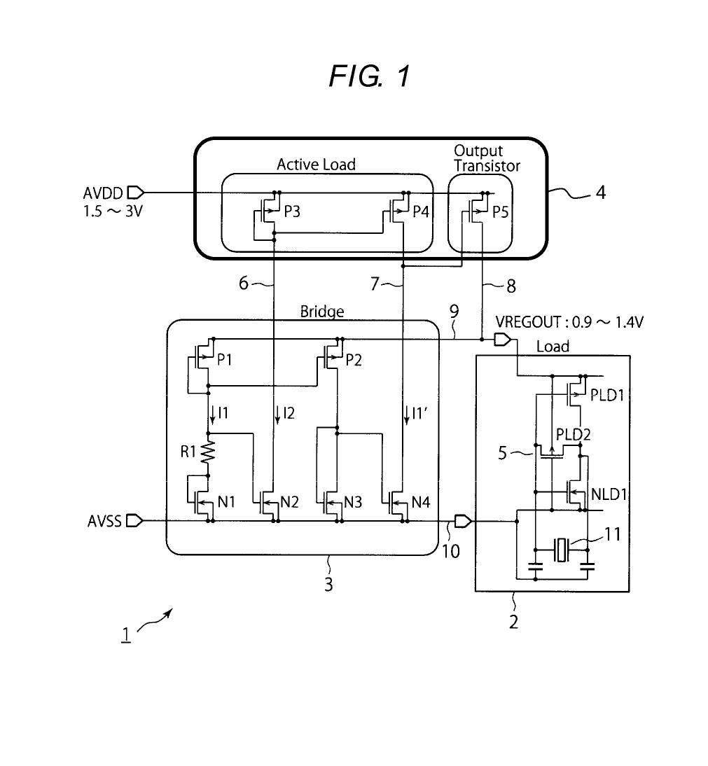

FIG. 1 is a circuit diagram of a power circuit 1 according to a first embodiment. The power circuit 1 shown in FIG. 1 is used for driving a load circuit 2 including a CMOS inverter, and includes a bridge circuit 3 and a current amplifier 4.

The bridge circuit 3 generates the current I2 flowing in a first current channel 6 and the current I1′ flowing in a second current channel 7, as a differential current I1′, 12, in accordance with the voltage difference between the output voltage VREGOUT and a predetermined set voltage to be supplied to the load circuit 2.

The current amplifier 4 generates a current flowing in a third current channel 8 leading to the load circuit 2 in accordance with the difference error current between the current I2 in the first current channel 6 and the current I1′ in the second current channel 7.

The bridge circuit 3 includes a diode-connected PMOS transistor (first MOS transistor) P1, a resistor (first impedance element) R1, and a diode-connected NMOS transistor (second MOS transistor) N1 connected in series between a first node 9 set to the output voltage VREGOUT and a second node 10 set to a reference voltage (for example, ground voltage AVSS). In the following description, it is assumed that the resistance of the resistor R1 is R1.

Further, the bridge circuit 3 includes an NMOS transistor (third MOS transistor) N2 which controls a current in the first current channel 6 in accordance with the voltage difference between the ground voltage AVSS and the voltage of the connection node between the PMOS transistor P1 and the resistor R1.

Still further, the bridge circuit 3 includes a PMOS transistor (fourth MOS transistor) P2 and an NMOS transistor (fifth MOS transistor) N3 connected in series between the first node 9 and the second node 10.

Still further, the bridge circuit 3 includes an NMOS transistor (sixth MOS transistor) N4 which controls a current in the second current channel 7 in accordance with the voltage of the connection node between the PMOS transistor P2 and the NMOS transistor N3.

The PMOS transistors P1 and P2 constitute a current mirror circuit, and the NMOS transistors N3 and N4 similarly constitute a current mirror circuit. According to this structure, the current I1′ that is equal to a drain current I1 of the PMOS transistor P1 multiplied by the mirror ratios of the two current mirror circuits flows in the second current channel 7 connected to the drain of the NMOS transistor N4. Thus, the current I1 and the current I1′ are currents correlated with each other.

The current amplifier 4 includes a third PMOS transistor P3 having a diode connection to the first current channel 6, a fourth PMOS transistor P4 as a current mirror of the third PMOS transistor P3, where the fourth PMOS transistor P4 is connected to the second current channel 7, and the output transistor P5 is connected to a third current channel 8. The third PMOS transistor P3 and the fourth PMOS transistor P4 act as active loads. The output transistor P5 supplies a current to the third current channel 8. The gate of the output transistor P5 is connected to the drain of the fourth PMOS transistor P4 and its output current is controlled by the drain-to-source voltage of the fourth PMOS transistor P4.

Source terminal of the third PMOS transistor P3, the fourth PMOS transistor P4, and the output transistor P5 are commonly connected to a power input terminal AVDD. The specific structure of the current amplifier 4 is not limited to the structure shown in FIG. 1.

The load circuit 2 includes the amplifier 5 having the CMOS inverter, and a crystal device 11, for example. The amplifier 5 includes a PMOS transistor PLD1 and an NMOS transistor NLD1 constituting the CMOS inverter, and a PMOS transistor PLD2 functioning as a resistor.

The specific structure of the load circuit 2 is not limited to the structure shown in FIG. 1. It should be understood, however, that at least the amplifier 5 containing the CMOS inverter is provided within the load circuit 2.

The PMOS transistor P1 and the NMOS transistor N2 within the bridge circuit 3 are configured so as to be symmetric with respect to the PMOS transistor PLD1 and the NMOS transistor NLD1 constituting the CMOS inverter in the load circuit 2, respectively. More specifically, the PMOS transistor P1 and the NMOS transistor N2 and the PMOS transistor PLD1 and the NMOS transistor NLD1 are manufactured by a common process where the electric characteristics of the respective transistors are the same or proportional to each other. In other words, the ratio of W/L of the PMOS transistor P1 to W/L of the PMOS transistor PLD1 is equalized with the ratio of W/L of the NMOS transistor N2 to W/L of the NMOS transistor NLD1. In this context, “W” indicates the channel width, while “L” indicates the gate length.

According to this structure, a current flowing in the amplifier 5 containing the CMOS inverter within the load circuit 2 can be adjusted using the current flowing within the bridge circuit 3.

A transconductance gm of the amplifier 5 containing the CMOS inverter is set in accordance with the electric characteristics of the PMOS transistor PLD1 and the NMOS transistor NLD1 constituting the CMOS inverter within the load circuit 2. Based on this setting, the set voltage to be supplied to the load circuit 2 and the set current to be supplied to the load circuit 2 for obtaining the minimum gm allowing normal operation of the amplifier 5 are determined. The bridge circuit 3 and the current amplifier 4 perform feedback control such that the output voltage VREGOUT of the bridge circuit 3 may be equal to the set voltage, and that a current flowing in the load circuit 2 can be the set current.

The value βN1 (=W/L) of the NMOS transistor N1 and the value of βN2 (=W/L) of the NMOS transistor N2 within the bridge circuit 3 are proportional to each other, and the relation βN2>βN1 holds.

Whether the drain current I1 of the NMOS transistor N1 is larger or smaller than the drain current I2 of the NMOS transistor N2 varies in accordance with the level of the output voltage VREGOUT. More specifically, while the current I1 is small, the voltage drop by the resistor R1 is similarly small. In this case, the gate voltage of the NMOS transistor N2 is low, wherefore the current I2 of the NMOS transistor N2 becomes smaller than the current I1. As the current I1 gradually increases, the gate voltage of the NMOS transistor N2 similarly increases little by little. In time, the current I2 becomes larger than the current I1.

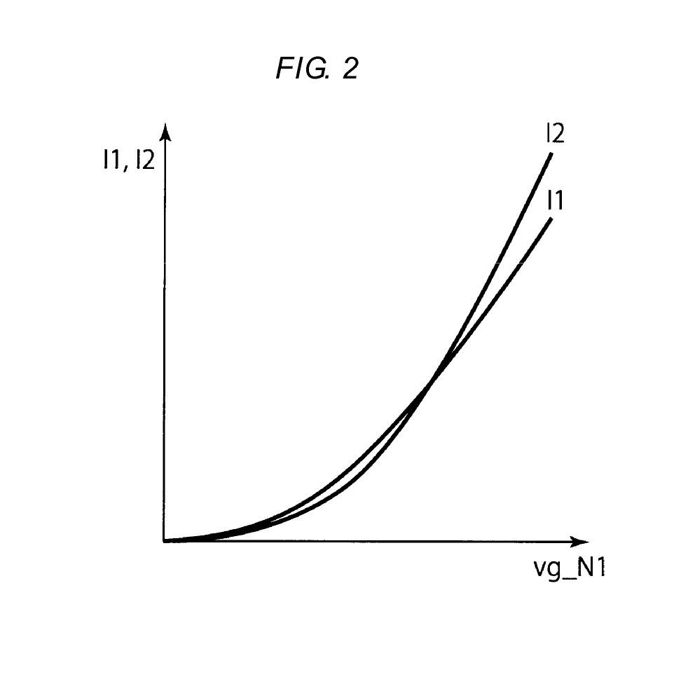

FIG. 2 is a graph showing changes of the current I1 and the current I2 in relation to the gate voltage of the transistor N1. In this graph, the horizontal axis represents a gate voltage Vg_N1 of the transistor N1, while the vertical axis represents the drain current. As can be seen from the figure, the current I1 and the current I2 cross each other when the gate voltage of the transistor N1 becomes a predetermined voltage. The current corresponding to the crossing point is the set current to be supplied to the load circuit 2, while the output voltage VREGOUT corresponding to the crossing point is the set voltage to be supplied to the load circuit 2.

Accordingly, when the output voltage VREGOUT deviates from the set voltage, the bridge circuit 3 and the current amplifier 4 perform feedback control for matching the output voltage VREGOUT with the set voltage and for matching the current flowing in the load circuit 2 with the set current by supplying a current corresponding to the difference error current to the load circuit 2 via the third current channel 8 in accordance with the deviation.

The values of the current I1 and the current I2 equalized with each other are expressed by the following equation (1).

$$\begin{matrix}I 1 = I 2 \\ = \frac{2}{R {1}^{2} \times {β}_{N 2}} {( 1 - \frac{1}{\sqrt{K}} )}^{2}\end{matrix} \qquad ( 1 )$$

In this equation, “K” is expressed by the following equation (2).

$$\begin{matrix}K = \frac{{β}_{N 1}}{{β}_{N 2}} \\ = \frac{{( \frac{W}{L} )}_{N 1}}{{( \frac{W}{L} )}_{N 2}}\end{matrix} \qquad ( 2 )$$

The transconductance gm of the NMOS transistor N2 is expressed by the following equation (3).

gm=\sqrt{2β_{N2}×I2} (3)

When K=4, gm=1/R1 holds based on the equations (1) and (3). It can be found that the value gm is not affected by process fluctuations in the characteristics of the NMOS transistor N2.

As found from the equation (1), the position of the crossing point between the currents I1 and I2 is determined in accordance with the resistance of the resistor R1 and the ratio of W/L of the NMOS transistor N1 to W/L of the NMOS transistor N2. Also, the output voltage VREGOUT is determined by a threshold voltage Vth and W/L of the transistors P1 and N1, and the ratio of W/L of the transistor N1 to W/L of the transistor N2, and the resistance of the resistor R1.

Next, the details of the operations of the bridge circuit 3 and the current amplifier 4 within the power circuit 1 shown in FIG. 1 are explained.

When the output voltage VREGOUT is lower than the set voltage, the current I1 becomes small. In this case, the voltage drop by the resistor R1 is small, wherefore the gate voltage of the NMOS transistor N2 is low. As a result, the relationship I1>I2 holds as shown in FIG. 2.

The PMOS transistors P1 and P2 and the NMOS transistors N3 and N4 constitute current mirror circuits, respectively. Thus, a current proportional to the current I1 flowing in the PMOS transistor P1 flows in each of the transistors P2, N3, and N4. In FIG. 1, the current flowing in the NMOS transistor N4 is shown as the current I1′. The term “proportional” in this context refers to the condition in which a current equal to the current I1 multiplied by the mirror ratio α of the current mirror circuit flows. Then the current I1′>α*I1

On the other hand, in current amplifier 4, the PMOS transistors P3 and P4 constitute a current mirror circuit of mirror ratio α. Then, a larger differential current (I1′−αI2) caused by lower VREGOUT than set voltage cause a larger voltage drop between source and drain of the fourth PMOS transistor P4 or gate to source voltage of the output transistor P5, and cause a larger drain current of the output transistor P5 or the third current channel 8. In addition, a larger current in the third current channel 8 causes a higher output voltage VREGOUT.

These operations realize feedback control in such a manner as to adjust the difference error current to zero (match the current αI2 with the current I1′). As a result, the current flowing in the load circuit 2 becomes the set current, and the output voltage VREGOUT supplied to the load circuit 2 becomes the set voltage by the feedback control.

Accordingly, in the first embodiment, by such feedback control where the set voltage necessary for the amplifier 5 containing the CMOS inverter within the load circuit 2 is applied to the load circuit 2 as the output voltage VREGOUT to obtain the minimum transconductance gm allowing normal operation, an ideal set current may flow in the load circuit 2. Therefore, current consumption can decrease.

For realizing such feedback control, in this embodiment, the bridge circuit 3 connected parallel to load circuits, and no high resistance resistor is required. Thus, the circuit area may considerably decrease. For realizing such feedback control, in this embodiment, only three current channels are employed, and naturally less current consumption can be achieved than employing more current channels.

### Second Embodiment

In the first embodiment discussed above, feedback control of the current flowing in the load circuit 2 is achieved while the current at the crossing point of the current I1 and the current I2 shown in the graph of FIG. 2 is determined as the set current for the load circuit 2. However, according to the equation (1) disclosed above, the current I1 and the current I2 are inversely proportional to the square of the resistance of the resistor R1, wherefore the current consumption of the load circuit 2 greatly fluctuates in accordance with variations of the resistance.

In order to reduce the fluctuations in the current consumption, it is preferable to operate the NMOS transistors N1 and N2 in a weak inversion area. In this case, the relationship expressed by the following equation (4) holds on the assumption that the current I1 and the current I2 are equal to each other.

$$\begin{matrix}I 1 = I 2 \\ = \frac{kT}{q} \times \frac{In ( K )}{R 1}\end{matrix} \qquad ( 4 )$$

In this equation, q is charge of electron, k is Boltzmann's constant, and T is absolute temperature.

As is apparent from the equation (4), the current I1 and the current I2 become inversely proportional to the resistance of the resistor R1 when the NMOS transistors N1 and N2 operate in a weak inversion area. Thus, fluctuations in the current consumption caused by variations of the resistance may be more greatly reduced than the case of the equation (1).

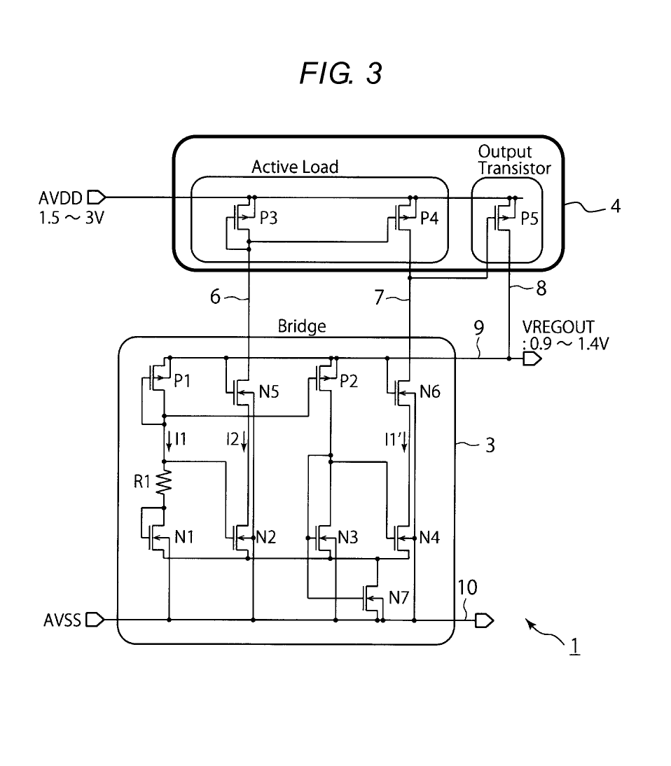

For operating a transistor in a weak inversion area, the value of W/L should be enlarged. Thus, in this embodiment, W/L of the NMOS transistors N1 through N4 shown in FIG. 1 is larger than that value in the first embodiment. Though fluctuations caused by R1 variation is smaller than in FIG. 1, when W/L of the NMOS transistors N1 through N4 is increased, each voltage between the gates and the sources of these transistors drops. In such a case, the output voltage VREGOUT similarly drops. Accordingly, as illustrated in FIG. 3, it is preferable to connect an NMOS transistor (ninth MOS transistor) N7 between the sources of the NMOS transistors N1 through N4 and the ground voltage. The gate of the NMOS transistor N7 is connected to the gate of the NMOS transistor N3, for example.

The NMOS transistors N1, N2, N3, N4, and N7 can be approximated by a single transistor in which the sum of the currents flowing between the drains and the sources of the respective NMOS transistors N1 through N4 flows and has the gate of the NMOS transistor N7 as a common gate. Accordingly, it is possible to realize substantial symmetry with respect to the operation point of the NMOS transistor NLD1 within the load circuit 2 by appropriately setting a size of the NMOS transistor N7.

A resistor Rds between the drain and the source of each of the NMOS transistors N2 and N4 operating in a weak inversion area is lower than the Rds of the transistors within the load circuit 2 operating in a strong inversion area, wherefore the gain of the negative feedback loop drops. It is, therefore, preferable to insert NMOS transistors (seventh and eighth MOS transistors) N5 and N6 and realize a cascode connection as illustrated in FIG. 3. Since the gates of the NMOS transistors N5 and N6 can be set to the output voltage VREGOUT, an additional cascode bias generating circuit for setting these gates is not needed. The NMOS transistor N5 is connected in series with the NMOS transistor N2 along the first current channel 6. The NMOS transistor N6 is connected in series with the NMOS transistor N4 along the second current channel 7.

The NMOS transistor N7 and the NMOS transistors N5 and N6 are provided for different purposes. Thus, such a structure which includes only one of the NMOS transistor N7, and the NMOS transistors N5 and N6 may be adopted.

Thus, according to the second embodiment the NMOS transistors N1 through N4 are operated in a weak inversion area. Thus, it is possible to decrease fluctuations in the current consumption of the load circuit 2.

In addition, in the second embodiment, the NMOS transistor N7 is connected between the sources of the NMOS transistors N1 through N4 operating in a weak inversion area and the ground voltage. In this structure, it is possible to eliminate the possibility of a drop of the output voltage VREGOUT.

Furthermore, in the second embodiment, the NMOS transistors N5 and N6 for providing a cascode connection structure are included for each of the NMOS transistors N2 and N4 operating in a weak inversion area. Thus, the gain of the negative feedback loop can improve.

### Third Embodiment

In a third embodiment described herein, the gate voltages of the NMOS transistors N5 and N6 added in FIG. 3 are optimized.

In the power circuit 1 shown in FIG. 3, the gates of the NMOS transistors N5 and N6 are set to the output voltage VREGOUT. In such a case, the output voltage VREGOUT decreases in accordance with a drop of the input source voltage AVDD. As a result, a voltage VDS between the drain and the source of each of the NMOS transistors N5 and N6 lowers, wherefore it is difficult to improve the gain of the negative feedback loop.

For overcoming this problem, in this embodiment, the connection target of the gates of the NMOS transistors N5 and N6 to a target is different from that of the structure shown in FIG. 3.

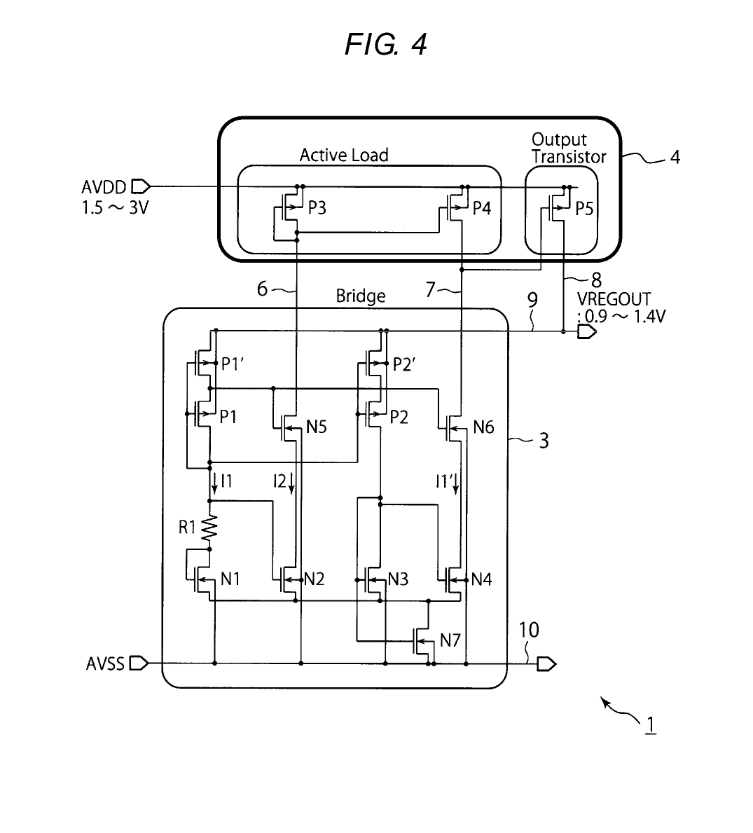

FIG. 4 is a circuit diagram showing the power circuit 1 according to the third embodiment. In the power circuit 1 shown in FIG. 4, a PMOS transistor P1′ connected in series with the PMOS transistor P1, and a PMOS transistor P2′ connected in series with the PMOS transistor P2 are added to the structure shown in FIG. 3. In the power circuit 1 in this embodiment, the intermediate node between the PMOS transistors P1 and P1′ is connected to the gate of the NMOS transistor N5, and the intermediate node between the PMOS transistors P1 and P1′ is connected to the gate of the NMOS transistor N6.

The voltage of the intermediate node is a voltage lower than the output voltage VREGOUT, preventing a drop of the voltage VDS between the drain and the source of each of the NMOS transistors N5 and N6.

According to the example shown in FIG. 4, the two PMOS transistors P1 and P1′ are connected in series, and the two PMOS transistors P2 and P2′ are similarly connected in series. However, the number of the transistors connected in series may be three or larger. In this case, the intermediate nodes of the respective transistors connected in series are connected to the gates of the NMOS transistors N5 and N6.

As apparent from above, in the third embodiment, since each of the PMOS transistors P1 and P2 is connected in series and the respective intermediate nodes thereof are connected to the gates of the NMOS transistors N5 and N6, each gate voltage of the NMOS transistors N5 and N6 is decreased to a voltage lower than the voltage in the second embodiment. According to this structure, it is possible to decrease the gate voltages of the NMOS transistors N5 and N6, wherefore it is possible to improve the gain of the negative feedback loop.

### Fourth Embodiment

A fourth embodiment discussed herein includes an auxiliary power source and a starter circuit. The auxiliary power source may be a capacitor or a small battery.

The power circuit 1 according to the first through third embodiments disclosed above does not operate when the output voltage VREGOUT is 0V, and therefore requires a starter circuit to cope with this condition. The starter circuit is not a part of this invention, and not shown here.

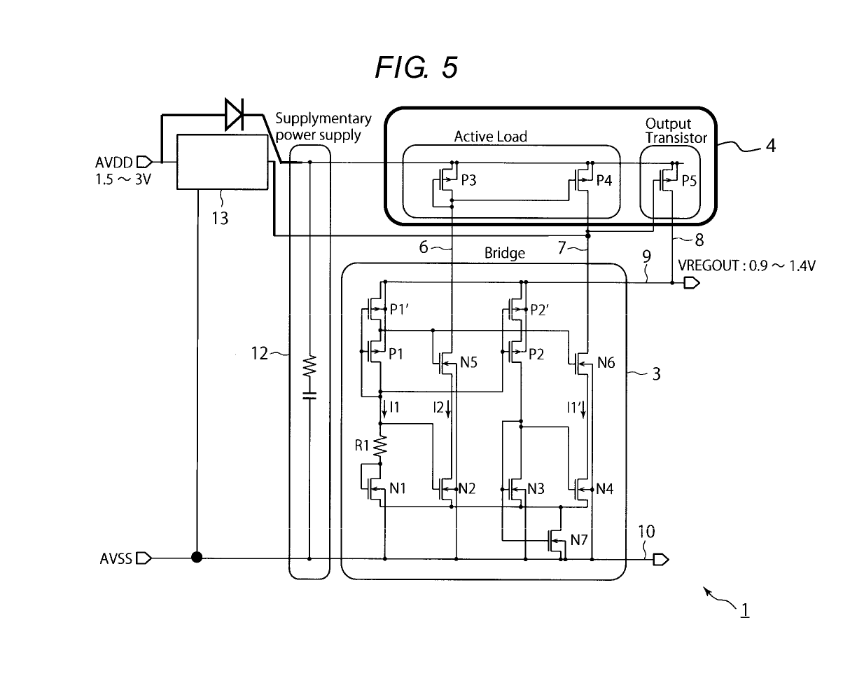

FIG. 5 is a circuit diagram showing the power circuit 1 according to the fourth embodiment. FIG. 5 illustrates a structure which adds an auxiliary power source 12 and a starter circuit 13 to the power circuit 1 shown in FIG. 4. However, the auxiliary circuit 12 and the starter circuit 13 also may be added to the power circuit 1 shown in FIG. 1 or 3.

In the power circuit 1 illustrated in FIG. 5, the starter circuit 13 is arranged on the upstream side of the auxiliary power source 12. The starter circuit 13 is not driven by the output voltage from the auxiliary power source 12 but by the power source voltage from a main power source. The starter circuit 13 consumes no current from the auxiliary power source 12. Thus, adding the starter circuit on the upstream side of the auxiliary power source 12 does not decrease the operation time with auxiliary power source and without external main power source.

### Fifth Embodiment

A fifth embodiment discussed herein contains steps taken for reducing fluctuations in the current flowing in the load circuit 2.

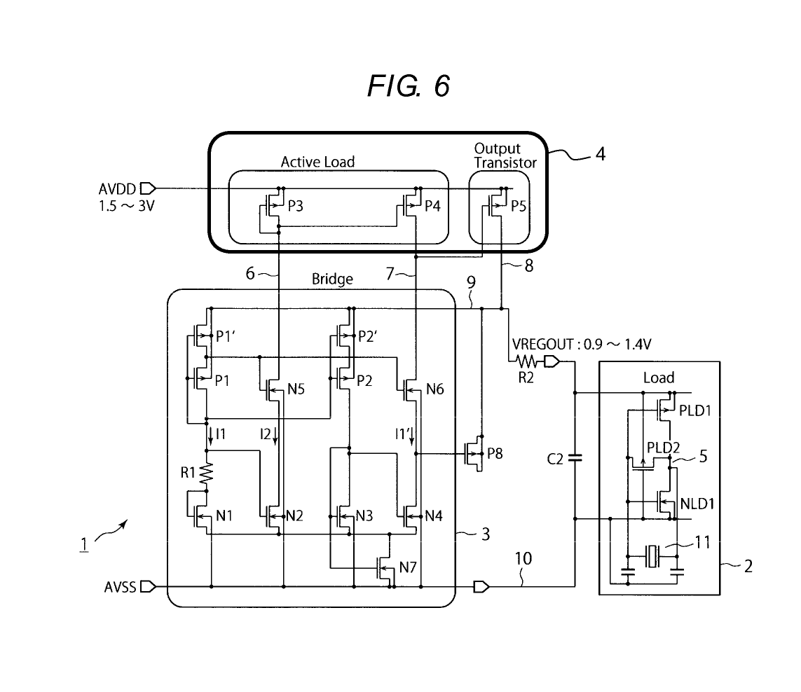

FIG. 6 is a circuit diagram showing the power circuit 1 according to the fifth embodiment. In the power circuit 1 shown in FIG. 6, a resistor R2, a capacitor C2, and a phase compensation capacitor P8 are added to the structure of the bridge circuit 3 shown in FIG. 4.

When fluctuations in the current flowing in the load circuit 2 (hereinafter, referred to as load current) are excessively large, the gate voltage of each of the transistors within the bridge circuit 3 becomes lower than the threshold voltage Vth. In this case, a dead time may be produced and cause oscillation.

For avoiding this situation, the resistor R2 is inserted to the node of the output voltage VREGOUT, and the capacitor C2 is connected between this node and the ground voltage. By providing the resistor R2, the bridge circuit 3 is not easily affected by fluctuations of the load current. Moreover, by providing the capacitor C2, a load current can be supplied from the capacitor C2 at the time of the rise of the load current.

The phase compensation capacitor P8 may be provided within the bridge circuit 3. The phase compensation capacitor P8 is a PMOS transistor P8. The gate of the PMOS transistor P8 is connected with the connection nodes of the NMOS transistors N4 and N6, while the drain and the source of the PMOS transistor P8 are connected with the node of the output voltage VREGOUT. According to this structure, the PMOS transistor P8 functions as a capacitor.

In the case of the structure including the phase compensation capacitor P8, the potentials of the connection nodes of the NMOS transistors N4 and N6 increase due to the capacitive coupling when the output voltage VREGOUT rises. As a result, the NMOS transistor N6 shifts in the direction of OFF, whereby the gate voltage of the PMOS transistor P5 rises. Accordingly, the drain current of the PMOS transistor P5 decreases, and the output voltage VREGOUT drops. In addition, the pole frequency of the gate of the PMOS transistor P5 lowers, in which condition phase compensation takes place.

While the resistor R2, the capacitor C2, and the phase compensation capacitor P8 are added to the bridge circuit 3 shown in FIG. 6, a structure which includes at least one of these components R2, C2, and P8 may be adopted.

According to the fifth embodiment which inserts the resistor R2 to the node of the output voltage VREGOUT, the bridge circuit 3 is not easily affected by fluctuations of the load current. Moreover, since the capacitor C2 is provided between the node of the output voltage VREGOUT and the ground voltage, a current can be supplied from the capacitor C2 at the time of fluctuations of the load current. Accordingly, fluctuations of the output voltage VREGOUT caused by fluctuations of the load current can decrease. Furthermore, the phase compensation capacitor P8 provided herein can reduce fluctuations of the output voltage VREGOUT, whereby power source noise sensitivity lowers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power circuit, comprising:
a bridge circuit connected to a first node by which an output voltage is supplied to a load circuit including an amplifier containing a CMOS inverter, and configured to generate a current flowing in a first current channel and a current flowing in a second current channel in accordance with a voltage difference between the output voltage and a predetermined set voltage to be supplied to the load circuit; and
a current amplifier configured to generate a current flowing in a third current channel to the load circuit in accordance with an input source voltage and a difference between the current flowing in the first current channel and the current flowing in the second current channel.

2. The power circuit according to claim 1, wherein
the bridge circuit comprises:
a diode-connected first MOS transistor of a first conductivity type, a first impedance element, and a diode-connected second MOS transistor of a second conductivity type, connected in series between a first node set to the output voltage and a second node set to a reference voltage;
a third MOS transistor of the second conductivity type that controls a current in the first current channel in accordance with a voltage of a connection node between the first MOS transistor and the first impedance element;
a fourth MOS transistor of the first conductivity type and a diode-connected fifth MOS transistor of the second conductivity type, connected in series between the first node and the second node; and
a sixth MOS transistor of the second conductivity type that controls a current in the second current channel in accordance with a voltage of a connection node between the fourth MOS transistor and the fifth MOS transistor, and
the first, fourth, fifth, and sixth MOS transistors constitute current mirror circuits.

3. The power circuit according to claim 2, further comprising:
a seventh MOS transistor of the second conductivity type connected in series with the third MOS transistor along the first current channel, and an eighth MOS transistor of the second conductivity type connected in series with the sixth MOS transistor along the second current channel,
wherein the respective gates of the seventh MOS transistor and the eighth MOS transistor are connected with the first node.

4. The power circuit according to claim 3, further comprising:
a ninth MOS transistor of the second conductivity type, connected between the second node and the respective sources of the second MOS transistor, the third MOS transistor, the fifth MOS transistor, and the sixth MOS transistor,
wherein a gate of the ninth MOS transistor is connected with a gate of the fifth MOS transistor.

5. The power circuit according to claim 4, wherein
each of the first MOS transistor and the fourth MOS transistor comprises a plurality of MOS transistors connected in series, and
each of the gates of the seventh MOS transistor and the eighth MOS transistor is connected with an intermediate node connecting the corresponding plural MOS transistors.

6. The power circuit according to claim 5, further comprising:
a second impedance element inserted between the bridge circuit and the load circuit.

7. The power circuit according to claim 6, further comprising:
a capacitor connected between the second impedance element and the second node.

8. The power circuit according to claim 7, further comprising:
a phase compensation capacitor connected between the first node and a connection node between the eighth MOS transistor and the sixth MOS transistor.

9. The power circuit according to claim 1, wherein the load circuit includes a crystal device.

10. The power circuit according to claim 1, wherein the predetermined set voltage supplied to the load circuit achieves a smallest transconductance during normal operation of the amplifier.

11. The power circuit according to claim 1, wherein the current amplifier is further connected to an auxiliary input source voltage.

12. The power circuit according to claim 1, further comprising:
a starter circuit configured to supply the input source voltage to the current amplifier.

13. A method of driving a load circuit including an amplifier containing a CMOS inverter, comprising:
generating an output voltage supplied to the load circuit;
generating currents respectively flowing in first and second current channels in accordance with a voltage difference between the output voltage and a predetermined set voltage to be supplied to the load circuit; and
generating a current flowing in a third current channel to the load circuit in accordance with an input source voltage and a difference between the current flowing in the first current channel and the current flowing in the second current channel.

14. The method according to claim 13, wherein the input source voltage to the current amplifier is supplied from a starter circuit.

15. The method according to claim 13, wherein the load circuit includes a crystal device.

16. The method according to claim 13, wherein the predetermined set voltage supplied to the load circuit achieves a smallest transconductance during normal operation of the amplifier.

17. A power circuit, comprising:
a first circuit configured to generate and supply a current to a load circuit including an amplifier containing a CMOS inverter, in accordance with an input source voltage and a difference between a first current and a second current; and
a second circuit configured to generate the first and second currents in accordance with a voltage difference between an output voltage of a first node connected between the second circuit and the load circuit and a predetermined set voltage to be supplied to the load circuit, the second circuit including
a diode-connected first MOS transistor of a first conductivity type, a first impedance element, and a diode-connected second MOS transistor of a second conductivity type, connected in series between the first node and a second node set to a reference voltage;
a third MOS transistor of the second conductivity type that controls the first current in accordance with a voltage of a connection node between the first MOS transistor and the first impedance element;
a fourth MOS transistor of the first conductivity type and a diode-connected fifth MOS transistor of the second conductivity type, connected in series between the first node and the second node; and
a sixth MOS transistor of the second conductivity type that controls the second current in accordance with a voltage of a connection node between the fourth MOS transistor and the fifth MOS transistor,
wherein the first, fourth, fifth, and sixth MOS transistors constituting current mirror circuits.

18. The power circuit according to claim 17, further comprising:
a second impedance element inserted between the second circuit and the load circuit.

19. The power circuit according to claim 18, further comprising:
a capacitor connected between the second impedance element and the second node.

20. The power circuit according to claim 19, further comprising:
a phase compensation capacitor connected between the first node and a drain of the sixth MOS transistor.
